(19) United States
(12) Patent Application Publication
(10) Pub. No.: US 2005/0090570 A1
(43) Pub. Date: Apr. 28, 2005

(54) Composition for forming dielectric film and method for forming dielectric film or pattern using the composition

(76) Inventors: Yi Yeol Lyu, Daejeon-Si (KR); Jin Heong Yim, Daejeon-Si (KR); Jong Back Seon, Yongin-Si (KR)

Correspondence Address: BIRCH STEWART KOLASCH & BIRCH, PO BOX 747, FALLS CHURCH, VA, 22040-0747, US

(21) Appl. No.: 10/808,374

(22) Filed: Mar. 25, 2004

(30) Foreign Application Priority Data
Oct. 28, 2003 (KR) 2003-75438

(51) Int. Cl. H01L 21/4763

(52) U.S. Cl. 521/50.5; 521/99

(57) ABSTRACT

A composition for forming a porous dielectric film which is prepared by dissolving a siloxane-based precursor containing hydroxyl groups or alkoxy groups and a pore-generating material together with a condensation catalyst generator capable of curing the siloxane-based resin precursor, in an organic solvent. The porous dielectric film has a low dielectric constant and improved physical properties and is formed by coating the composition onto a substrate, followed by light exposure to cause polycondensation at low temperature. A method for forming a negative pattern of a porous dielectric film is also provided without the use of a photoresist by exposing the coated film to light through a mask, and removing unexposed regions with a developing agent.

### BACKGROUND OF THE INVENTION

This non-provisional application claims priority under 35 U.S.C. § 119(a) to Korean Patent Application No. 2003-75438 filed on Oct. 28, 2003, which is herein incorporated by reference.

1. Field of the Invention

The present invention relates to a composition for forming a dielectric film and a method for forming a dielectric film or pattern using such a composition. More particularly, the present invention relates to a composition for forming a porous dielectric film comprising (i) a siloxane-based resin precursor, (ii) a condensation catalyst generator, (iii) a pore-generating material and (iv) a solvent capable of dissolving the components (i)˜(iii); and a method for forming a porous dielectric film or pattern using such a composition.

2. Description of the Related Art

As the degree of integration in the semiconductor device increases, the capacity of the interlayer insulating film should be decreased to lower the resistance and capacity of the wirings. For this purpose, attempts have been made to use low dielectric constant materials for interlayer dielectric films of semiconductor devices. For instance, U.S. Pat. Nos. 3,615,272, 4,399,266 and 4,999,397 disclose polysilsesquioxanes having a dielectric constant of about 2.5˜3.1 prepared by spin-on deposition (SOD), which can replace SiO₂ having a dielectric constant of about 4.00 prepared by a conventional chemical vapor deposition (CVD) technique. Further, U.S. Pat. No. 5,965,679 teaches polyphenylenes as organic polymers having a dielectric constant of 2.65-2.70. However, these dielectric constants are not sufficiently low to satisfy an increasing demand to fabricate high-speed devices requiring a low dielectric constant, below 2.50. For this reason, there have been a number of trials to incorporate air having a dielectric constant of 1.0 into an organic or inorganic material at a nanometer-scale. U.S. Pat. No. 6,231,989 suggests a method for forming a porous thin film by mixing a high boiling point solvent capable of forming pores and hydrogen silsesquioxane, and treating the mixture with ammonia. A further method for preparing a low dielectric constant material is found in U.S. Pat. Nos. 6,107,357 and 6,093,636. According to this method, first, a porogen in a dendrimer form is formed from regularly sized vinyl-based polymer particles capable of being decomposed at the thin film-forming stage, as taught in U.S. Pat. No. 6,114,458. Thereafter, a particular amount of the porogen is mixed with an organic or inorganic matrix to form a thin film, and is then decomposed at high temperature to form nano-scale pores. More recently, a method for forming a porous dielectric film by employing a polyalkyleneoxide-based amphiphillic surfactant as a porogen has been suggested in U.S. Pat. Nos. 6,204,202, 6,413,882, 6,423,770 and 6,406,794. However, according to this method, pores are at least partially or completely connected to each other, and eventually the physical properties of the dielectric film become deteriorated. In addition, this method has the disadvantage that chemicals and metal atoms used as materials for an interlayer dielectric film having a low dielectric constant in the manufacture of semiconductor devices are diffused. Accordingly, it is critical to reduce the size and the interconnectivity of pores to be formed.

On the other hand, micropatterning is indispensable in order to apply the low dielectric constant film to devices. As a typical micropatterning technique, a photolithography technique using a photoresist (PR) made of a photosensitive polymer-based resin is generally used. A variety of techniques for micropatterning of a porous silica applicable to a low dielectric constant film have been suggested, e.g., soft lithography[P. D. Yang et al., Science 282, 2244 (1998), M. Trau et al., Nature, 390, 674 (1997)], inkjet printing[H. Y. Fan et al., Nature, 405, 56(2000), U.S. Pat. No. 6,471,761(2002)], etc. D. A. Doshi et al. proposed a method for forming a pattern of a porous silica thin film by using a photoacid generator having a long hydrocarbon chain, which simultaneously performs the roll as a surfactant forming pores and the function as an acid catalyst responding to UV light[D. A. Doshi et al., Science, 290, 107 (2000) and U.S. Patent Laid-open No. 2002-0127498]. Since this method, however, uses a tetraethoxysilane (TEOS) as a matrix precursor in the preparation of a coating solution and begins from a sol-gel reaction in the presence of water and an acid catalyst, it is assumed to have difficulty in its commercial applications in terms of poor reproducibility and storage stability.

### SUMMARY OF THE INVENTION

Therefore, the present invention has been made in view of the above problems, and a feature of the present invention is to provide a dielectric film having a low dielectric constant and improved thin film physical properties wherein the dielectric film is formed by adding a condensation catalyst generator to a dielectric film-forming composition to cause a low-temperature polycondensation after light exposure.

Another feature of the present invention is to provide a method for forming a negative pattern of a dielectric film without the use of a photoresist by exposing a film prepared by the composition containing a condensation catalyst generator to light through a mask, followed by developing the film.

In accordance with a feature of the present invention, there is provided a composition for forming a porous dielectric film, comprising (i) a siloxane-based resin precursor, (ii) a condensation catalyst generator, (iii) a pore-generating material, and (iv) a solvent for dissolving the components (i)˜(iii).

In accordance with another feature of the present invention, there is provided a method for forming a porous dielectric film, comprising the steps of: (1) coating the above composition onto a substrate to form a thin film; (2) exposing the thin film to light and low temperature curing the exposed thin film at a temperature of 50˜150° C.; and (3) heating the thin film at a temperature higher than the decomposition temperature of the pore-generating material.

In accordance with still another feature of the present invention, there is provided a method for forming a pattern of a porous dielectric film, comprising the steps of: (1) coating the above composition onto a substrate to form a thin film; (2) exposing the thin film to light through a patterned mask and low temperature curing the exposed thin film at a temperature of about 50˜150° C.; (3) removing unexposed regions with a developing agent to form a negative pattern; and (4) heating the negative pattern at a temperature higher than the decomposition temperature of the pore-generating material.

In accordance with still another feature of the present invention, there are provided a porous dielectric film and pattern prepared by the above method.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The above and other objects, features and other advantages of the present invention will be more clearly understood from the following detailed description taken in conjunction with the accompanying drawings, in which:

FIGS. 1a to 1f are optical microscope images of the pattern of a dielectric film formed in Example 3 of the present invention; and

FIGS. 2a to 2f are scanning electron microscope (SEM) images of the pattern of a dielectric film formed in Example 3 of the present invention.

### DESCRIPTION OF THE PREFERRED EMBODIMENTS

Hereinafter, the present invention will be explained in more detail.

A composition for forming a dielectric film according to the present invention is prepared by dissolving a siloxane-based resin precursor containing hydroxyl groups or alkoxy groups and a pore-generating material together with a condensation catalyst generator for generating an acid or base catalyst capable of curing the siloxane-based resin precursor, in an organic solvent. A porous dielectric film having a low dielectric constant and improved physical properties can be formed by coating the composition onto a substrate to form a thin film, followed by light exposure to cause polycondensation at low temperature. A negative pattern of the porous dielectric film can be formed without the use of a photoresist by exposing a film of the composition to light through a mask, and removing the unexposed regions with a developing agent.

As the siloxane-based resin precursor contained in the composition of the present invention, there may be used (1) an organosilsesquioxane and (2) a siloxane-based polymer prepared by partially condensing a cyclic or cage-type siloxane monomer and at least one silane-based monomer selected from Si(OR)₄, RSi(OR)₃ and R₂Si(OR)₂ (in which R is an organic group) so as to have a number average molecular weight of 1,000˜1,000,000.

Specific examples of the organosilsesquioxanes include hydrogen silsesquioxanes, alkyl silsesquioxanes, aryl silsesquioxanes and copolymers thereof.

More preferred siloxane-based resin precursors are organic polysiloxane-based resins having a silanol group (Si—OH) content of 10 mole % or more, and preferably 25 mole % or more, thus exhibiting superior solubility.

The organic polysiloxane-based resin is prepared by hydrolysis and polycondensation of a cyclic siloxane monomer represented by Formula 1 below: 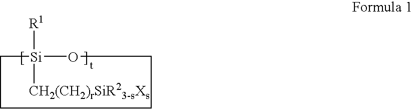
wherein R¹ and R² are each independently a hydrogen atom, a C_{1˜3} alkyl group, a C_{3˜10} cycloalkyl group or a C_{6˜15} aryl group, X is a halogen atom or a C_{1˜5} alkoxy group, r is an integer of from 0 to 10, s is an integer of from 1 to 3 and t is an integer of from 3 to 8,
and at least one monomer selected from the group consisting of silane-based monomers represented by Formulae 2 to 4 below:
   Formula 2
   SiX¹X²X³X⁴
wherein X¹, X², X³ and X⁴ are each independently a halogen atom or a C_{1˜5} alkoxy group;
   Formula 3
   R¹SiX¹X²X³
wherein R¹ is a hydrogen atom, a C_{1˜3} alkyl group, a C_{3˜10} cycloalkyl group or a C_{6˜15} aryl group, and X¹, X² and X³ are as defined above; and
   Formula 4
   R¹R²SiX¹X²
wherein R¹ and R² are each independently a hydrogen atom, a C_{1˜3} alkyl group, a C_{3˜10} cycloalkyl group or a C_{6˜15} aryl group, and X¹ and X² are as defined above, in the presence of an acid or base catalyst.

Examples of the acid catalyst used in the condensation for preparing the siloxane-based resins include, but are not limited to, hydrochloric acid, nitric acid, benzene sulfonic acid, oxalic acid and formic acid. Examples of the base catalyst preferably include, but are not limited to, potassium hydroxide, sodium hydroxide, triethylamine, sodium bicarbonate and pyridine.

The equivalence ratio of the water used during the hydrolysis and condensation to reactive groups of the monomers is in the range of 1.0˜100.0, and preferably 1.0˜10.0. The reaction is carried out at a temperature of about 0˜200° C. and preferably about 50˜110° C. for 1˜100 hours and preferably 5˜24 hours.

The condensation catalyst generator contained in the composition of the present invention specifically refers to a photoacid generator or photobase generator, each of which generates an acid or base by light exposure or heating.

Specific examples of the photoacid generator usable in the present invention include compounds represented by Formulae 5 to 7 below: 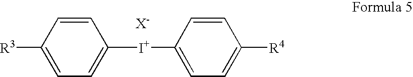
wherein R³ and R⁴ are each independently a hydrogen atom, a C_{1˜6} alkyl group, a C_{3˜10} cycloalkyl group or a C_{6˜15} aryl group, and X is a sulfonate derivative; 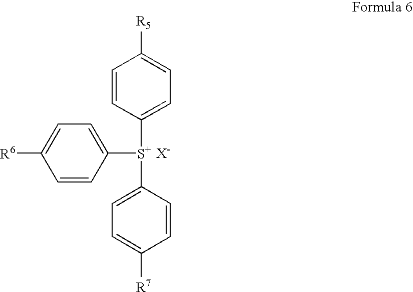
wherein R⁵, R⁶ and R⁷ are each independently a hydrogen atom, a C_{1˜6} alkyl group, a C_{3˜10} cycloalkyl group or a C_{6˜15} aryl group, and X is a sulfonate derivative; and 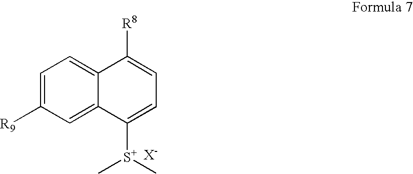
wherein R⁸ and R⁹ are each independently a hydrogen atom, a hydroxyl group, a C_{1˜6} alkyl group, a C_{3˜10} cycloalkyl group or a C_{6˜15} aryl group, and X is a sulfonate derivative.

As examples of the compound of Formula 5, diphenyliodonium trifluoromethane sulfonate, diphenyliodonium nonafluoromethane sulfonate and di-(4-t-butylbenzene)iodonium trifluoromethane sulfonate and the like can be mentioned.

As examples of the compound of Formula 6, triphenylsulfonium trifluoromethane sulfonate, triphenylsulfonium nonafluoromethane sulfonate, diphenyl 4-methylphenylsulfonium trifluoromethane sulfonate, triphenylsulfonium p-toluene sulfonate, triphenylsulfonium 10-camphor sulfonate and the like can be mentioned.

As concrete examples of the compound of Formula 7, dimethyl(4-naphthol)sulfonium trifluoromethane sulfonate, dimethyl(4-naphthol)sulfonium p-toluene sulfonate, dimethyl(4,7-dihydroxy-naphthalene)sulfonium trifluoromethane sulfonate, dimethyl(4,7-dihydroxy-naphthalene)sulfonium 10-camphor sulfonate, dimethyl(4,7-dihydroxy-naphthalene)sulfonium p-toluene sulfonate, dimethyl(4,7-dihydroxy-naphthalene)sulfonium nonafluoromethane sulfonate, dimethyl(4,7-dihydroxy-naphthalene)sulfonium 3-pyridine sulfonate and the like can be mentioned.

Specific examples of the photobase generator usable in the present invention include compounds represented by Formula 8 below: 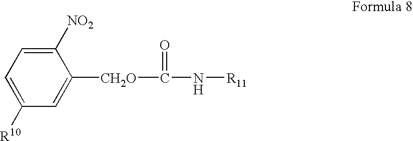
wherein R¹⁰ is a hydrogen atom, a hydroxyl group, a C_{1˜6} alkyl group, a C_{3˜10} cycloalkyl group or a C_{6˜15} aryl group, and R¹¹ is a cyclohexyl, naphthyl, adamantyl, nitrophenyl or methoxyphenyl group.

As examples of the compound of Formula 8, N-{(2-nitrobenzyl)oxycarbonyl}cyclohexyl amine, N-{(2-nitrobenzyl)oxycarbonyl}1-naphthyl amine, N-{(2-nitrobenzyl)oxycarbonyl}1-adamantyl amine, N-{(2-nitrobenzyl)oxycarbonyl}3-nitroaniline, N-{(2-nitrobenzyl)oxycarbonyl}4-methoxyaniline, N-{(5-methyl-2-nitrobenzyl)oxycarbonyl}cyclohexyl amine, N-{(5-methyl-2-nitrobenzyl)oxycarbonyl}1-naphthyl amine, N-{(5-methyl-2-nitrobenzyl)oxycarbonyl}1-adamantyl amine, N-{(5-methyl-2-nitrobenzyl)oxycarbonyl}3-nitroaniline and N-{(5-methyl-2-nitrobenzyl)oxycarbonyl}4-methoxyaniline and the like can be mentioned.

The pore-generating material contained in the composition of the present invention includes any material known in the art that can form pores. Representative examples of the pore-generating material include a polyethylene oxide represented by Formula 9 below:

Formula 9
R¹³CH₂ₙOCH₂CH₂ₘOR¹²
wherein R¹² and R¹³ are each independently a hydrogen atom, a C_{2˜30} acyl group, a C_{1˜20} alkyl group or —Sir¹r²r³ (in which r¹, r² and r³ are each independently a hydrogen atom, a C_{1˜6} alkyl group, a C_{1˜6} alkoxy group or a C_{6˜20} aryl group), m is an integer of from 20 to 80, and n is an integer of from 2 to 200;
a polyethylene oxide-propylene oxide block copolymer represented by Formula 10 below: 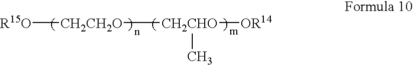
wherein R¹⁴ and R¹⁵ are each independently a hydrogen atom, a C_{2˜30} acyl group, a C_{1˜20} alkyl group or —Sir¹r²r³ (in which r¹, r² and r³ are each independently a hydrogen atom, a C_{1˜6} alkyl group, a C_{1˜6} alkoxy group or a C_{6˜20} aryl group), and m and n are as defined above;
a polyethylene oxide-propylene oxide-ethylene oxide triblock copolymer represented by Formula 11 below: 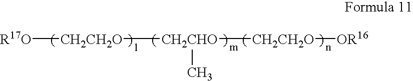
wherein R¹⁶ and R¹⁷ are each independently a hydrogen atom, a C_{2˜30} acyl group, a C_{1˜20} alkyl group or —Sir¹r²r³ (in which r¹, r² and r³ are each independently a hydrogen atom, a C_{1˜6} alkyl group, a C_{1˜6} alkoxy group or a C_{6˜20} aryl group), 1 is an integer of from 2 to 200, and m and n are as defined above;
a cyclodextrin derivative represented by Formula 12 below: 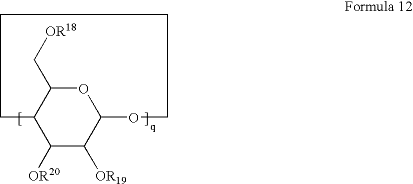
wherein R¹⁸, R¹⁹ and R²⁰ are each independently a hydrogen atom, a C_{2˜30} acyl group, a C_{1˜20} alkyl group or —Sir¹r²r³ (in which r¹, r² and r³ are each independently a hydrogen atom, a C_{1˜6} alkyl group, a C_{1˜6} alkoxy group or a C_{6˜20} aryl group), and q is an integer of from 5 to 8; and
a polycarprolactone dendrimer represented by Formula 13 below: 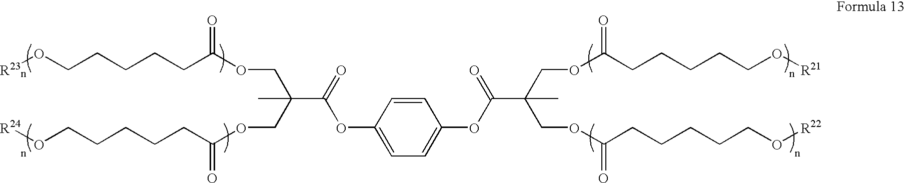
wherein R²¹, R²², R²³ and R²⁴ are each independently a hydrogen atom, a C_{2˜30} acyl group, a C_{1˜20} alkyl group or —Sir¹r²r³ (in which r¹, r² and r³ are each independently a hydrogen atom, a C_{1˜6} alkyl group, a C_{1˜6} alkoxy group or a C_{6˜20} aryl group), and n is an integer of from 2 to 200.

The composition of the present invention is prepared by dissolving the siloxane-based resin precursor, the condensation catalyst generator and the pore-generating material in a proper solvent. Specific examples of solvents for this purpose include, but are not particularly limited to, aromatic hydrocarbon-based solvents such as anisole, xylene and mesitylene; ketone-based solvents such as methyl isobutyl ketone and acetone; ether-based solvents such as tetrahydrofuran and isopropyl ether; acetate-based solvents such as propylene glycol mono methyl ether acetate; alcohol-based solvents such as isopropyl alcohol and butyl alcohol; amide-based solvents such as dimethylacetamide and dimethylformamide; γ-butyrolactone; silicon solvents; and mixtures thereof.

The solvent should be contained in such an amount that the siloxane-based resin precursor can be coated onto a substrate. This amount of the solvent is preferably 20˜99.9 parts by weight, and more preferably 50˜95 parts by weight, based on 100 parts by weight of the composition (the siloxane-based resin precursor+the condensation catalyst generator+the pore-generating material+the solvent).

The amount of the condensation catalyst generator is preferably in the range of 0.1˜20 parts by weight, and more preferably 1˜10 parts by weight, based on 100 parts by weight of the total solid content (the siloxane-based resin precursor+the condensation catalyst generator+the pore-generating material) in the composition of the present invention. The amount of the pore-generating material is preferably in the range of 0.1˜95 parts by weight, and more preferably 10˜70 parts by weight, based on 100 parts by weight of the total solid content (the siloxane-based resin precursor+the condensation catalyst generator+the pore-generating material) in the composition of the present invention.

The present invention also provides a method for forming a porous dielectric film using the composition. In accordance with the method of the present invention, a dielectric film is formed on a semiconductor substrate, acting as an interlayer dielectric film for semiconductors. First, the composition is coated onto a substrate by spin coating, dip coating, spray coating, flow coating or screen printing. The application is preferably carried out by spin coating at a speed of 1,000˜5,000 rpm.

Next, the resulting substrate is exposed to X-ray, ion beam or electron beam to generate a condensation catalyst from the condensation catalyst generator, and is then cured at a relatively low temperature of about 50˜150° C. to induce polycondensation between the Si—OH groups present in the siloxane-based resin precursor, thereby forming a thin film insoluble to solvents.

In the case of forming a pattern of the dielectric film, the coated film is exposed to light through a mask, followed by development. Suitable developing agents usable in the present invention include the above-mentioned solvents used in the preparation of the composition of the present invention but are not limited in this regard.

The coated film thus formed is heated to a temperature of about 150˜600° C., and more preferably about 200˜450° C., to decompose the pore-generating material, thereby forming a crack-free thin film containing nano-sized pores. The crack-free thin film used herein means a thin film including no cracks when observed by an optical microscope with a magnification of 1,000×, and the insoluble thin film means a thin film substantially insoluble to the above-mentioned solvents useful for dissolving the siloxane-based resin. The heating of the coating film may be carried out under an inert atmosphere such as nitrogen or argon, or in a vacuum. The curing can be carried out for up to 10 hours, and preferably for 30 minutes to 1 hour.

When a dielectric film is formed by using about 30 parts by weight of the pore-generating material relative to 100 parts by weight of the total solid content in the composition, it exhibits a low dielectric constant and excellent physical properties when compared to those formed without undergoing the low temperature curing step. Accordingly, the dielectric film formed by the method of the present invention is very useful for application to semiconductor devices. Further, a patterned siloxane-based resin dielectric film can be obtained in a simple process of exposing the coated film through a mask and developing it.

Hereinafter, the present invention will be described in more detail with reference to the following preferred examples. However, these examples are given for the purpose of illustration and are not to be construed as limiting the scope of the present invention.

### EXAMPLE 1

### Synthesis of Siloxane Monomer

29.014 mmol (10.0 g) of 2,4,6,8-tetramethyl-2,4,6,8-tetravinylcyclotetrasiloxane and 0.164 g of a solution of platinum(O)-1,3-divinyl-1,1,3,3-tetramethyldisiloxane complex in xylenes are put into a flask, and then 300 ml of diethyl ether is added thereto to dilute the mixture. After the mixture is cooled to −78° C., 127.66 mmol (17.29 g) of trichlorosilane is slowly added to the mixture. The reaction temperature is gradually raised to room temperature. At this temperature, the reaction is continued for 20 hours. After completion of the reaction, volatile substances are completely evaporated at reduced pressure of about 0.1 torr and 100 ml of pentane is added to the concentrate. The resulting mixture is stirred for 1 hour and filtered through celite to obtain a colorless clear solution. The pentane is evaporated at reduced pressure (˜0.1 torr) to prepare the compound [—Si(CH₃)(CH₂CH₂SiCl₃)O—]₄ as a colorless liquid in a yield of 95%. Next, 11.28 mmol (10.0 g) of the compound is diluted in 500 ml of tetrahydrofuran, and then 136.71 mmol (13.83 g) of triethylamine is added thereto. After the mixture is cooled to −78° C., 136.71 mmol (4.38 g) of methyl alcohol is added thereto. The reaction temperature is gradually raised to room temperature. At this temperature, the reaction is continued for 15 hours. After completion of the reaction, the reaction mixture is filtered through celite, and then the filtrate is concentrated at reduced pressure of about 0.1 torr to completely evaporate volatile substances. 100 ml of pentane is added to the concentrate. The resulting mixture is stirred for 1 hour and filtered through celite to obtain a colorless clear solution. The pentane is evaporated at reduced pressure (˜0.1 torr) to prepare monomer A of Formula 14 as a colorless liquid in a yield of 94%:

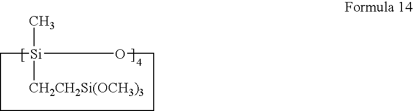

### EXAMPLE 2

### Polymerization of Siloxane-Based Resin Precursor (Copolymer of Monomer A and Methyltrimethoxysilane)

After 37.86 mmol (5.158 g) of methyltrimethoxysilane and 3.79 mmol (3.162 g) of the monomer A are charged into a flask, the mixture is diluted in 100 ml of tetrahydrofuran. Separately, water and concentrated hydrochloric acid (containing 35% hydrogen chloride) are mixed in a ratio of 100:0.12 (v/v) to prepare a hydrochloric acid in which the hydrogen chloride is present in an amount of 0.0159 mmol. The hydrochloric acid is added to the previous mixture and then water was added dropwise thereto until the total amount of water, including water contained in the hydrochloric acid, reached 529.6 7 mmol (9.534 g). The reaction temperature is gradually increased to 70° C. At this temperature, the reaction was continued for 16 hours. The reaction solution is transferred to a separatory funnel, and then 100 ml of diethyl ether is added thereto. After the obtained aqueous phase is washed with 100 ml of water five times, 5 g of sodium sulfate (anhydrous) is added thereto. The resulting mixture is stirred at room temperature for 10 hours to remove a small quantity of remaining water, and filtered to obtain a colorless clear solution. Volatile substances are evaporated from the solution at reduced pressure of about 0.1 torr to prepare 5.5 g of siloxane-based resin precursor B as a white powder. The molecular weight of precursor B and the molecular weight distribution are determined by gel permeation chromatography (manufactured by Waters Corp.). As a result, the weight average molecular weight (Mw) of precursor B is 4194, and the molecular weight distribution (MWD) is 2.50. The contents (%) of Si—OH, Si—OCH₃ and Si—CH₃ present at the end groups of the siloxane-based resin are identified through NMR (Bruker) analysis. As a result, the contents of Si—OH (%), Si—OCH₃ and Si—CH₃ are 28.9%, 0.7% and 70.4%, respectively.

### EXAMPLE 3

### Formation of Patterned Porous Thin Film

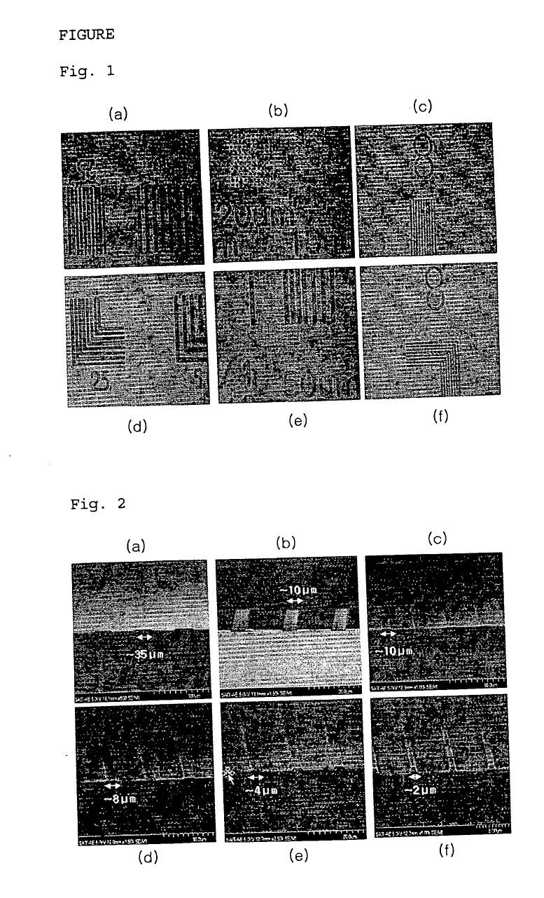

0.6 g of the siloxane-based resin precursor prepared in Example 2, 0.257 g of heptakis(2,3,6-tri-O-methyl)-β-cyclodextrin as a pore-generating material and 0.03 g of triphenylsulfonium trifluoromethane sulfonate as a photoacid generator are completely dissolved in 1.5 g of propylene glycol methyl ether acetate to prepare a coating solution. The coating solution is spin-coated onto a boron-doped p-type silicon wafer at 3,000 rpm. The resulting wafer is covered with a patterned mask, and is then exposed to UV light through the mask in a UV exposure system (wavelength: 256 nm) for 900 seconds. The exposed wafer is then placed on a hot plate at 120° C. for 3 minutes. The resulting wafer structure is immersed in propylene glycol methyl ether acetate as a developing solvent, washed with ethanol and dried to form a desired dielectric film pattern. In order to make the film porous, a hard cure process of the film is performed at 420° C. for 1 hour under vacuum condition. All of heptakis(2,3,6-tri-O-methyl)-β-cyclodextrins in the patterned film are effectively removed at this stage. FIGS. 1a to 1f show optical microscope images of the dielectric film pattern, and FIGS. 2a to 2f show scanning electron microscope (SEM) images of the dielectric film pattern.

### EXAMPLE 4

### Measurement of Dielectric Constant and Physical Properties of thin Film

0.6 g of the siloxane-based resin precursor prepared in Example 2, 0.257 g of heptakis(2,3,6-tri-O-methyl)-β-cyclodextrin as a pore-generating material, and various photoacid or photobase generators having the contents as indicated in Table 1 are completely dissolved in 1.5 g of propylene glycol methyl ether acetate to prepare respective coating solutions. The coating solutions are spin-coated onto different boron-doped p-type silicon wafers at 3,000 rpm. The resulting wafers are covered with a patterned mask, and are then exposed to UV light through the mask in a UV exposure system (wavelength: 256 nm) for 900 seconds. After the exposed wafers are then placed on a hot plate at 120° C. for 3 minutes, they are subjected to soft baking at 150° C. for 1 minute and at 250° C. for 1 minute, sequentially, to completely remove the organic solvent. The resulting substrates are cured in a Linberg furnace under vacuum at 420° C. for 60 minutes to form low dielectric constant films. The thin film elastic modulus and hardness of the low dielectric constant films are measured using a nanoindentor (manufactured by MTS Corp.). The results are listed in Table 1 below. The measured values are obtained from 9 points of the films, and then averaged.

Meanwhile, the dielectric constant of the porous thin films is measured in accordance with the following procedure. First, thermally oxidized silicon films are applied onto boron-doped p-type silicon wafers to a thickness of 3,000 Å, respectively, and then 100 Å-thick titanium thin films and 2,000 Å-thick aluminum thin films are sequentially deposited onto the respective silicon films using a metal evaporator. Thereafter, the low dielectric constant thin films are coated onto the resulting structures, after which spherical aluminum thin films having a diameter of 1 mm are deposited on the resulting structures to a thickness of 2,000 Å using a hardmask designed so as to have an electrode diameter of 1 mm, to form MIM (metal-insulator-metal)-structured low dielectric constant thin films. The capacitance of the thin films is measured at a frequency of around 100 kHz using a PRECISION LCR METER (HP4284A) accompanied with a probe station (Micromanipulatior 6200 probe station). The thickness of the thin films is measured using a prism coupler. The dielectric constant (k) of the thin films is calculated according to the following equation:
k=C×d/ε₀×A

where k is the relative dielectric constant, C is the capacitance, d is the thickness of the low dielectric constant thin film, ε₀ is the permittivity of a vacuum, and A is the contact cross-sectional area of the electrode.

TABLE 1

| | | Content of | Relative | | |
|---|---|---|---|---|---|
| | Condensation | catalyst | dielectric | Hard- | Elastic |
| Example | catalyst | generator | constant | ness | Modulus |
| No. | generator | (wt %) | (k) | (GPa) | (GPa) |
| Example | TPS-TFMS⁽¹⁾ | 1 | 2.14 | 3.94 | 0.68 |
| 4-1 | | | | | |
| Example | TPS-TFMS | 5 | 2.12 | 3.97 | 0.69 |
| 4-2 | | | | | |
| Example | TPS-TFMS | 10 | 2.05 | 3.93 | 0.68 |
| 4-3 | | | | | |
| Example | TPS-TFMS | 5 | 1.91 | 3.51 | 0.57 |
| 4-4 | | | | | |
| Example | TPS-PTS⁽²⁾ | 5 | 2.18 | 3.53 | 0.62 |
| 4-5 | | | | | |
| Example | TPS-CS⁽³⁾ | 5 | 2.13 | 3.51 | 0.64 |
| 4-6 | | | | | |
| Example | NBOC-CHA⁽⁴⁾ | 5 | 2.12 | 3.66 | 0.65 |
| 4-7 | | | | | |
| Comparative | — | — | 2.20 | 3.38 | 0.56 |
| Example | | | | | |

⁽¹⁾TPS-TFMS: Triphenylsulfonium trifluoromethane sulfonate
⁽²⁾TPS-PTS: Triphenylsulfonium p-toluene sulfonate
⁽³⁾TPS-CS: Triphenylsulfonium 10-camphor sulfonate
⁽⁴⁾NBOC-CHA: (2-Nitrobenzyl)oxycarbonyl cyclohexylamine

### EXAMPLE 5

### Measurement of Pore Size of Porous Thin Film and Pore Size Distribution

Porous thin films are formed using the compositions indicated as shown in Table 2 below, in the same procedure described in Example 4. Toluene adsorption analysis is performed on the porous thin films using an Ellipsometry Porosimeter[EP10, XPEQT Corp.]. The results are shown in Table 2 below.

TABLE 2

| | | Content of | Pore- | |
|---|---|---|---|---|
| | Condensation | catalyst | generating | Average |
| | catalyst | generator | material | pore size |
| Example No. | generator | (g) | (g) | (Å) |
| Example 5-1 | TPS-TFMS | 0.03 | 0.257 | 18 |
| Example 5-2 | TPS-PTS | 0.03 | 0.257 | 16 |
| Example 5-3 | TPS-CS | 0.03 | 0.257 | 16 |
| Comparative | — | — | 0.257 | 24 |
| Example | | | | |

As can be seen from data shown in Table 2, the thin films formed using the compositions comprising a catalyst generator has smaller average pore sizes than the thin film formed using the composition comprising no catalyst generator.

As apparent from the above description, according to the composition of the present invention, a low dielectric constant film having a low dielectric constant and improved thin film physical properties can be formed. In addition, according to the method of the present invention, a negative pattern of a porous dielectric film can be formed without the use of a photoresist by exposing the dielectric composition to light through a patterned mask, and removing unexposed regions with a developing agent.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A composition for forming a porous dielectric film, comprising:
(i) a siloxane-based resin precursor;
(ii) a condensation catalyst generator;
(iii) a pore-generating material; and
(iv) a solvent for dissolving the components (i)˜(iii).

2. The composition according to claim 1, wherein the amount of the condensation catalyst generator is 0.1˜20 parts by weight, based on 100 parts by weight of the total solid content (the siloxane-based resin precursor+the condensation catalyst generator+the pore-generating material).

3. The composition according to claim 1, wherein the amount of the pore-generating material is 0.1˜95 parts by weight, based on 100 parts by weight of the total solid content (the siloxane-based resin precursor+the condensation catalyst generator+the pore-generating material).

4. The composition according to claim 1, wherein the siloxane-based resin precursor is selected from the group consisting of hydrogen silsesquioxane, an alkyl silsesquioxane, an aryl silsesquioxane and a copolymer thereof.

5. The composition according to claim 1, wherein the siloxane-based resin precursor is prepared by hydrolysis and polycondensation of at least one cyclic siloxane based monomer selected from the group consisting of compounds represented by Formula 1 below: 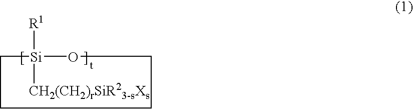
wherein R¹ and R² are each independently a hydrogen atom, a C_{1˜3} alkyl group, a C_{3˜10} cycloalkyl group or a C_{6˜5} aryl group, X is a halogen atom or a C_{1˜5} alkoxy group, r is an integer of from 0 to 10, s is an integer of from 1 to 3 and t is an integer of from 3 to 8,
and at least one silane-based monomer selected from the group consisting of compounds represented by Formulae 2 to 4 below:
SiX¹X²X³X⁴ (2)
wherein X¹, X², X³ and X⁴ are each independently a halogen atom or a C_{1˜5} alkoxy group;
R¹SiX¹X²X³ (3)
wherein R¹ is a hydrogen atom, a C_{1˜3} alkyl group, a C_{3˜10} cycloalkyl group or a C_{6˜15} aryl group, and X¹, X² and X³ are as defined above; and
R¹R²SiX¹X² (4)
wherein R¹ and R² are each independently a hydrogen atom, a C_{1˜3} alkyl group, a C_{3˜10} cycloalkyl group or a C_{6˜15} aryl group, and X¹ and X² are as defined above,
using an acid or base catalyst and water in an organic solvent.

6. The composition according to claim 5, wherein the acid catalyst is selected from the group consisting of hydrochloric acid, nitric acid, benzene sulfonic acid, oxalic acid and formic acid, and the base catalyst is selected from the group consisting of potassium hydroxide, sodium hydroxide, triethylamine, sodium bicarbonate and pyridine.

7. The composition according to claim 5, wherein the equivalence ratio of the water used during the hydrolysis and condensation to reactive groups of the monomers is in the range of 1.0˜100.0, and wherein the hydrolysis and condensation are carried out at a temperature of about 0˜200° C. for 1˜100 hours.

8. The composition according to claim 1, wherein the condensation catalyst generator is a photoacid generator or photobase generator capable of generating an acid or base by light exposure or heating.

9. The composition according to claim 8, wherein the photoacid generator is at least one compound selected from the group consisting of compounds represented by Formulae 5 to 7 below: 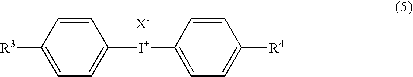
wherein R³ and R⁴ are each independently a hydrogen atom, a C_{1˜6} alkyl group, a C_{3˜10} cycloalkyl group or a C_{6˜15} aryl group, and X is a sulfonate derivative; 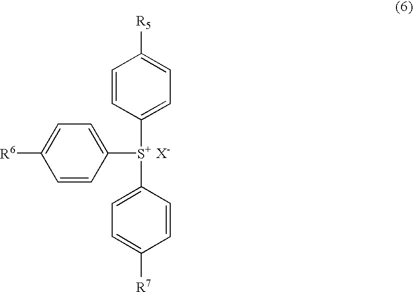
wherein R⁵, R⁶ and R⁷ are each independently a hydrogen atom, a C_{1˜6} alkyl group, a C_{3˜10} cycloalkyl group or a C_{6˜15} aryl group, and X is a sulfonate derivative; and 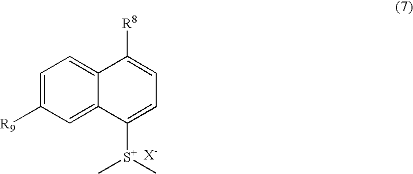
wherein R⁸ and R⁹ are each independently a hydrogen atom, a hydroxyl group, a C_{1˜6} alkyl group, a C_{3˜10} cycloalkyl group or a C_{6˜15} aryl group, and X is a sulfonate derivative.

10. The composition according to claim 8, wherein the photobase generator is a compound represented by Formula 8 below: 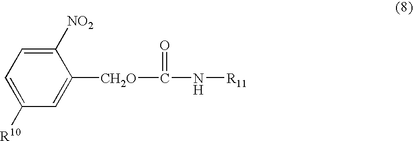
wherein R¹⁰ is a hydrogen atom, a hydroxyl group, a C_{1˜6} alkyl group, a C_{3˜10} cycloalkyl group or a C_{6˜15} aryl group, and R¹¹ is a cyclohexyl, naphthyl, adamantyl, nitrophenyl or methoxyphenyl group.

11. The composition according to claim 1, wherein the pore-generating material is at least one compound selected from the group consisting of compounds represented by Formulae 9 to 13 below:
R¹³CH₂ₙOCH₂CH₂OR¹² (9)
wherein R¹² and R¹³ are each independently a hydrogen atom, a C_{2˜30} acyl group, a C_{1˜20} alkyl group or —Sir¹r²r³ (in which r¹, r² and r³ are each independently a hydrogen atom, a C_{1˜6} alkyl group, a C_{1˜6} alkoxy group or a C_{6˜20} aryl group), m is an integer of from 20 to 80, and n is an integer of from 2 to 200; 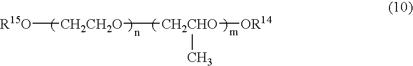
wherein R¹⁴ and R¹⁵ are each independently a hydrogen atom, a C_{2˜30} acyl group, a C_{1˜20} alkyl group or —Sir¹r²r³ (in which r¹, r² and r³ are each independently a hydrogen atom, a C_{1˜6} alkyl group, a C_{1˜6} alkoxy group or a C_{6˜20} aryl group), and m and n are as defined above; 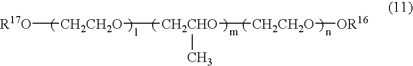
wherein R¹⁶ and R¹⁷ are each independently a hydrogen atom, a C_{2˜30} acyl group, a C_{1˜20} alkyl group or —Sir¹r²r³ (in which r¹, r² and r³ are each independently a hydrogen atom, a C_{1˜6} alkyl group, a C_{1˜6} alkoxy group or a C_{6˜20} aryl group), 1 is an integer of from 2 to 200, and m and n are as defined above; 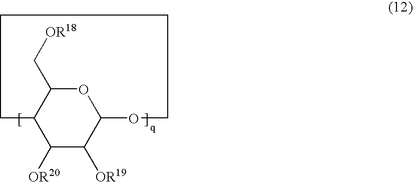
wherein R¹⁸, R¹⁹ and R²⁰ are each independently a hydrogen atom, a C_{2˜30} acyl group, a C_{1˜20} alkyl group or —Sir¹r²r³ (in which r¹, r² and r³ are each independently a hydrogen atom, a C_{1˜6} alkyl group, a C_{1˜6} alkoxy group or a C_{6˜20} aryl group), and q is an integer of from 5 to 8; and 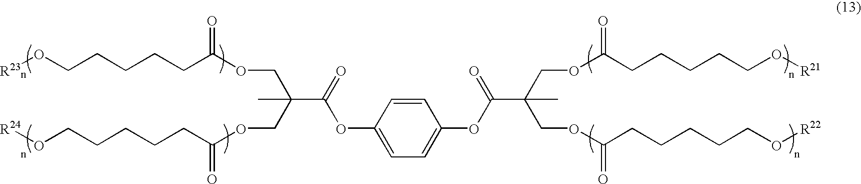
wherein R²¹, R²², R²³ and R²⁴ are each independently a hydrogen atom, a C_{2˜30} acyl group, a C_{1˜20} alkyl group or —Sir¹r²r³ (in which r¹, r² and r³ are each independently a hydrogen atom, a C_{1˜6} alkyl group, a C_{1˜6} alkoxy group or a C_{6˜20} aryl group), and n is an integer of from 2 to 200.

12. The composition according to claim 1, wherein the solvent is an aromatic hydrocarbon-based solvent, a ketone-based solvent, an ether-based solvent, an acetate-based solvent, an alcohol-based solvent, an amide-based solvent, γ-butyrolactone, a silicon solvent, or a mixture thereof.

13. The composition according to claim 1, wherein an amount of the solvent is 20˜99.9 parts by weight, based on 100 parts by weight of the composition (the siloxane-based resin precursor+the condensation catalyst generator+the pore-generating material+the solvent).

14. A method for forming a porous dielectric film, comprising the steps of:
(1) coating the composition according to claim 1 onto a substrate to form a thin film;
(2) exposing the thin film to light and low temperature curing the exposed thin film at a temperature of about 50˜150° C.; and
(3) heating the thin film at a temperature higher than the decomposition temperature of the pore-generating material.

15. The method according to claim 14, wherein the thin film is applied by spin coating, dip coating, spray coating, flow coating or screen printing.

16. The method according to claim 14, wherein the light exposure is carried out using X-ray, ion beam or electron beam.

17. A method for forming a pattern of a porous dielectric film, comprising the steps of:
(1) coating the composition according to claim 1 onto a substrate to form a thin film;
(2) exposing the thin film to light through a patterned mask and low temperature curing the exposed thin film at a temperature of about 50˜150° C.;
(3) removing unexposed regions with a developing agent to form a negative pattern; and
(4) heating the negative pattern at a temperature higher than the decomposition temperature of the pore-generating material.

18. The method according to claim 17, wherein the thin film is applied by spin coating, dip coating, spray coating, flow coating or screen printing.

19. The method according to claim 17, wherein the light exposure is carried out using X-ray, ion beam or electron beam.

20. A porous dielectric film prepared by the method according to claim 14.

21. A pattern of a porous dielectric film prepared by the method according to claim 17

22. A porous dielectric film prepared from a composition comprising:
(i) a siloxane-based resin precursor;
(ii) a condensation catalyst generator;
(iii) a pore-generating material; and
(iv) a solvent for dissolving the components (i)˜(iii).
